(19) United States
(12) Patent Application Publication
(10) Pub. No.: US 2023/0029163 A1
(43) Pub. Date: Jan. 26, 2023

(54) WAFER MAP ANALYSIS SYSTEM USING NEURAL NETWORK AND METHOD OF ANALYZING WAFER MAP USING THE SAME

(71) Applicant: Samsung Electronics Co., Ltd., Suwon-si (KR)

(72) Inventors: Minjoo KIM, Hwaseong-si (KR); Jungha KIM, Suwon-si (KR); Jinhyung TAK, Hwaseong-si (KR)

(73) Assignee: Samsung Electronics Co., Ltd., Suwon-si (KR)

(21) Appl. No.: 17/714,494

(22) Filed: Apr. 6, 2022

(30) Foreign Application Priority Data
Jul. 26, 2021 (KR) 10-2021-0098113

(51) Int. Cl. G06N 3/08

(52) U.S. Cl. CPC G06N 3/08

(57) ABSTRACT

A method of analyzing a wafer map using a neural network and a wafer map analysis system are provided. The method of analyzing a wafer map using a neural network includes creating a wafer map based on raw data, receiving, by an inception module including a plurality of inception layers, a first output feature map created based on the wafer map, outputting, by the inception module, a final inception output feature map based on the first output feature map, connecting the first output feature map to the final inception output feature map through a shortcut connection, and performing an addition operation on the first output feature map and the final inception output feature map to output a second output feature map.

### CROSS-REFERENCE TO RELATED APPLICATION

This application is based on and claims priority under 35 U.S.C. §119 to Korean Patent Application No. 10-2021-0098113, filed on Jul. 26, 2021, in the Korean Intellectual Property Office, the disclosure of which is incorporated by reference herein in its entirety.

### BACKGROUND

The inventive concepts relate to a wafer map analysis apparatus using a neural network and a method of analyzing a wafer map using the same, and more particularly, to a wafer map analysis apparatus for analyzing a defect type of a wafer map using a neural network and a method of analyzing a wafer map using the same.

Neural networks refer to computational architecture that models biological brains. As neural network technology has developed in recent years, research into analyzing input data received from the outside and extracting valid information using neural network devices in various fields has been actively conducted.

For example, in a manufacturing environment of integrated semiconductor devices, research for classifying a pattern of wafer maps using neural networks has continued. However, as semiconductor devices are integrated and patterns of wafer maps to be analyzed become more complex, computations to be processed using the neural networks increase dramatically, while computing resources are limited. Therefore, there is a need for a wafer map analysis apparatus and a wafer map analysis method of efficiently performing computational processing based on a neural network and accurately classifying defective types of a wafer map using limited computing resources.

### SUMMARY

The inventive concepts provide a wafer map analysis apparatus and a wafer map analysis method of efficiently performing computational processing based on a neural network and accurately classifying defective types of a wafer map using limited computing resources.

The technical problems of the inventive concepts are not limited to the technical problems mentioned above, and other technical problems not mentioned will be clearly understood by those skilled in the art from the following description.

According to an aspect of the inventive concepts, there is provided a method of analyzing a wafer map using a neural network, including creating a wafer map based on raw data; receiving, by an inception module including a plurality of inception layers, a first output feature map created based on the wafer map; outputting, by the inception module, a final inception output feature map based on the first output feature map; connecting the first output feature map to the final inception output feature map through a shortcut connection; and performing an addition operation on the first output feature map and the final inception output feature map to output a second output feature map.

According to another aspect of the inventive concepts, there is provided a method of analyzing a wafer map, including creating a first raw wafer map based on first raw data; creating a first wafer map by processing the first raw wafer map; and creating a deep learning model which has learned a defect pattern of the first map using a neural network, the creating of the deep learning model including creating a first output feature map by extracting characteristic information of the first wafer map using a first module configured to receive the first wafer map and performing subsampling on the characteristic information, creating a second output feature map based on the first output feature map using a second module configured to receive the first output feature map, and determining a defect type of the first wafer map based on the second output feature map using a third module configured to receive the second output feature map, and wherein the second module includes an inception module configured to receive the first output feature map, the inception module including a plurality of inception layers and a shortcut connection configured to connect the first output feature map to a final inception output feature map output of the inception module.

According to another aspect of the inventive concepts, there is provided a wafer map analysis system including a first pre-processing device configured to convert first raw data into a first raw wafer map and to create a first wafer map by processing the first raw wafer map, a second pre-processing device configured to convert second raw data, different from the first raw data, into a second raw wafer map and to create a second wafter map by processing the second raw wafer map, a neural network device configured to create a deep learning model by training the deep learning model with the first wafer map using a neural network, and an analysis device configured to analyze a pattern of the second wafer map using the deep learning model, wherein the neural network includes a first module configured to extract characteristic information of the first wafer map using a plurality of layers that are sequentially arranged and performing sub-sampling to create a first output feature map, a second module configured to extract characteristic information of the first output feature map using an inception module, and to create a second output feature map by performing sub-sampling, the inception module including a plurality of inception layers and a shortcut connection connecting the first output feature map to a final inception output feature map output of the inception module, and a third module configured to analyze a pattern of the first wafer map based on the second output feature map and determine a defect type of the first wafer map.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram of a wafer map analysis system according to some example embodiments;

FIG. 2 is a flowchart illustrating a method of analyzing a wafer map according to some example embodiments;

FIG. 3 is a view illustrating a wafer map according to some example embodiments;

FIG. 4 is a flowchart illustrating a method of analyzing a wafer map according to some example embodiments;

FIG. 5 is a flowchart illustrating a method of analyzing a wafer map according to some example embodiments;

FIG. 6 is a flowchart illustrating a method of analyzing a wafer map according to some example embodiments;

FIG. 7 is a view illustrating a structure of a neural network according to some example embodiments;

FIG. 8 is a view illustrating a structure of a first module according to some example embodiments;

FIG. 9 is a view illustrating a structure of a second module according to some example embodiments;

FIG. 10 is a view illustrating a structure of a second module according to some example embodiments;

FIG. 11 is a view illustrating a structure of an inception layer according to some example embodiments;

FIG. 12 is a view illustrating a structure of a third module according to some example embodiments;

FIG. 13 is a view illustrating a structure of a neural network according to some example embodiments;

FIG. 14 is a view illustrating processing according to some example embodiments;

FIG. 15 is a view illustrating a label of a wafer map;

FIG. 16 is a view illustrating processing according to some example embodiments;

FIG. 17 is a flowchart illustrating a method of manufacturing a semiconductor device according to some example embodiments;

FIG. 18 is a block diagram illustrating a method of manufacturing a semiconductor device according to some example embodiments; and

FIG. 19 is a block diagram illustrating a neural network device according to some example embodiments.

### DETAILED DESCRIPTION OF THE EMBODIMENTS

Hereinafter, various example embodiments of the inventive concepts are described with reference to the accompanying drawings. In describing with reference to the drawings, the same or corresponding components are given the same reference numerals, and redundant descriptions thereof are omitted.

Although the terms “first,” “second,” etc., may be used herein to describe various elements, components, regions, layers, and/or sections, these elements, components, regions, layers, and/or sections should not be limited by these terms, these terms are only used to distinguish one element, component, region, layer, or section, from another element, component, region, layer, or section. Thus, a first element, component, region, layer, or section, discussed below may be otherwise termed a second element, component, region, layer, or section, without departing from the scope of this disclosure.

Some example embodiments of the present disclosure may be represented by functional blocks and various processing operations. Some or all of such functional blocks may be implemented as various numbers of hardware and/or software components for performing specific functions.

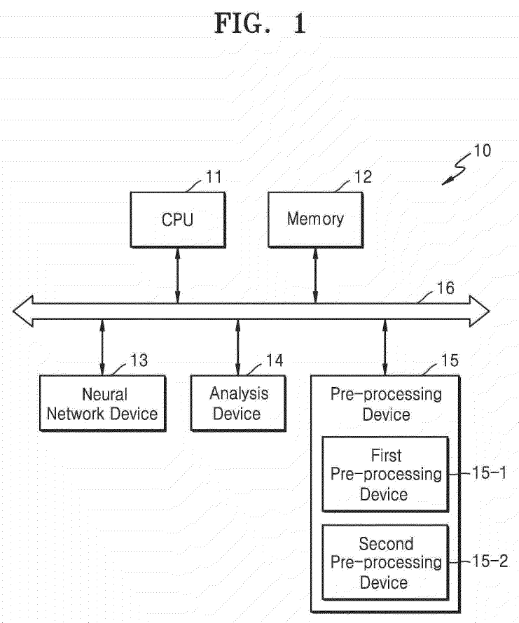

FIG. 1 is a block diagram of a wafer map analysis system 10 according to some example embodiments.

Referring to FIG. 1, the wafer map analysis system 10 may extract valid information from input data based on a neural network. Because the wafer map analysis system 10 performs a neural network computation function, the wafer map analysis system 10 may be defined as including a neural network system. The wafer map analysis system 10 may be, and/or be included in, an application processor. The wafer map analysis system 10 may be applied to image display devices, measurement devices, smart TVs, robots, and the like, and may be mounted on various types of electronic devices.

The wafer map analysis system 10 may include a central processing unit (CPU) 11, a memory 12, a neural network device 13, an analysis device 14, and a pre-processing device 15. Some or all of the CPU 11, the memory 12, the neural network device 13, the analysis device 14, and the pre-processing device 15 may be mounted in one semiconductor chip. For example, the wafer map analysis system 10 may be implemented as a system on chip (SoC). The components, that is, the CPU 11, the memory 12, the neural network device 13, the analysis device 14, and the pre-processing device 15, of the wafer map analysis system 10 may communicate with each other via a bus 16. The wafer map analysis system 10 may further include an input/output (I/O) module, a security module, a power control device, and various types of computing devices.

The CPU 11 may include one processor core (single core) or multiple processor cores (multi-core). The CPU 11 may control an overall operation of the wafer map analysis system 10. For example, the CPU 11 may control the memory 12, the neural network device 13, the analysis device 14, and/or the pre-processing device 15. The CPU 11 may execute a program stored in the memory 12 and/or process data. The CPU 11 may control a function of the neural network device 13 by executing the program stored in the memory 12. The CPU 11 may control the neural network device 13 to normally perform computation. For example, the CPU 11 may control the input/output (“I/O”) of data performed inside the neural network device 13, the I/O of data performed between the neural network device 13 and external components (e.g., the memory 12), and/or a computation process of the neural network device 13. The CPU 11 may control a function of the analysis device 14 using a deep learning model stored in the memory 12.

The memory 12 may store information and/or data obtained in the wafer map analysis system 10. The memory 12 may store an operating system (OS), programs, data, and algorithms related to the operation of the CPU 11. For example, the memory 12 may store test images provided to the neural network device 13 and/or a deep learning model created by the neural network device 13.

The memory 12 may include one or more memory devices. For example, the memory 12 may include a first memory storing raw data provided to the neural network device 13, a second memory storing programs provided to the neural network device 13, and/or a third memory storing the deep learning model created by the neural network device 13. In some embodiments, the memory 12 may be divided into regions, and the information and/or data may be stored in respective regions.

The memory 12 may include at least one of a volatile memory and/or a nonvolatile memory. For example, the memory 12 may include at least one of read only memory (ROM), programmable ROM (PROM), electrically programmable ROM (EPROM), electrically erasable and programmable ROM (EEPROM), flash memory, phase-change random access memory (PRAM), magnetic RAM (MRAM), resistive RAM (RRAM), ferroelectric RAM (FeRAM), dynamic RAM (DRAM), static RAM (SRAM), synchronous DRAM (SDRAM), and/or the like. For example, the memory 12 may include at least one of a hard disk drive (HDD), a solid state drive (SSD), a compact flash (CF) card, secure digital (SD), micro-SD card, and a mini-SD card, an extreme digital (xD) card, a memory stick, and/or the like.

The neural network device 13 may receive input data from the memory 12. The neural network device 13 may perform a neural network operation based on the received input data and create a deep learning model based on an operation result. For example, the neural network device 13 may create a deep learning model by learning using the input data received from the memory 12. The deep learning model may include a neural network model that determines a defect type by analyzing a pattern of a wafer map. In some example embodiments, the deep learning model created and/or modified by the neural network device 13 may be stored in the memory 12. The neural network device 13 may also be referred to as a computing device, a computing module, and/or the like.

The neural network may, for example, model a human brain structure, and may refer to a structure including numerous artificial neurons connected to each other based on connection strength and/or weights. The neural network may include various types of neural network models such as a convolution neural network (CNN), a region with convolution neural network (R-CNN), a region proposal network (RPN), a recurrent neural network (RNN), a stacking-based deep neural network (S-DNN), a state-space dynamic neural network (S-SDNN), a deconvolution network, a deep belief network (DBN), a restricted Boltzmann machine (RBM), a fully convolutional network, a long short-term memory (LSTM) network, a classification network, a gated recurrent unit (GRU), a stacked neural network (SNN), a generative adversarial network (GAN), etc., but is not limited thereto. Alternatively and/or additionally, the learning model may include other types of machine learning models, for example, linear and/or logistic regression, statistics clustering, Bayesian classification, determination trees, dimensional reduction such as main component analyses, expert systems, random forests, and/or a combination thereof.

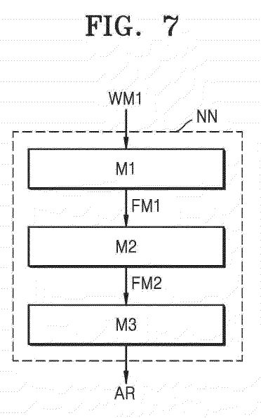

The neural network performing a single task may include sub-neural networks implemented by the neural network models described above. An example structure of the neural network, according to some example embodiments of the inventive concepts, is described in detail with reference to FIGS. 7 to 13 to be described below.

The analysis device 14 may analyze the wafer map using the deep learning model created by the neural network device 13. The analysis device 14 may receive data to be analyzed from, e.g., outside the analysis device 14 (and/or the wafer map analysis system 10) and may output an analysis result of the data to be analyzed using, e.g., a deep learning model. The analysis device 14 may include an I/O module for receiving new data and/or outputting an analysis result of the data.

The pre-processing device 15 may pre-process a received image. For example, the pre-processing device 15 may appropriately process the data stored in the memory 12 to be used in the neural network device 13. For example, the pre-processing device 15 may appropriately process the data input to the analysis device 14 to be analyzed using, e.g., the deep learning model. For example, in some example embodiments, the pre-processing device 15 may create a wafer map to be used in the neural network device 13 (and/or the analysis device 14) through processing the data input, such as converting raw data extracted by performing an electrical test on a wafer into an image and/or changing a size of the image. Hereinafter, the image converted from the raw data may be referred to as a ‘raw wafer map’, and the data processed through the pre-processing device 15 may be referred to as a ‘wafer map’.

In some example embodiments, the pre-processing device 15 may provide the created wafer map to the neural network device 13 (and/or the analysis device 14). In FIG. 1, the pre-processing device 15 is shown outside the neural network device 13, but is not limited thereto, and may be included in the neural network device 13. In FIG. 1, the pre-processing device 15 is shown outside the analysis device 14, but is not limited thereto and may be included in the analysis device 14.

The wafer map analysis system 10 may include one or more pre-processing devices 15. For example, the pre-processing device 15 may include a first pre-processing device 15-1 and a second pre-processing device 15-2. In some example embodiments, the first pre-processing device 15-1 may be included in the neural network device 13 and/or the second pre-processing device 15-2 may be included in the analysis device 14. The first pre-processing device 15-1 and the second pre-processing device 15-2 may create wafer maps having the same size and channel. Hereinafter, a case in which the pre-processing device 15 includes the first pre-processing device 15-1 and the second pre-processing device 15-2 is described, but the example embodiments are not limited thereto.

The wafer map analysis system 10 may further include other general-purpose components. For example, the wafer map analysis system 10 may further include additional memory such as a permanent storage (such as a disk drive), a communication port for communicating with an external device, a user interface device such as a touch panel, a key, a button, an accelerator, and/or the like. Hereinafter, a wafer map analysis method using the wafer map analysis system 10 is described in detail. For clarity, the drawings described below are described with reference to FIG. 1.

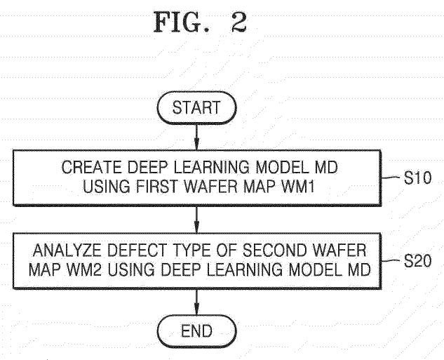

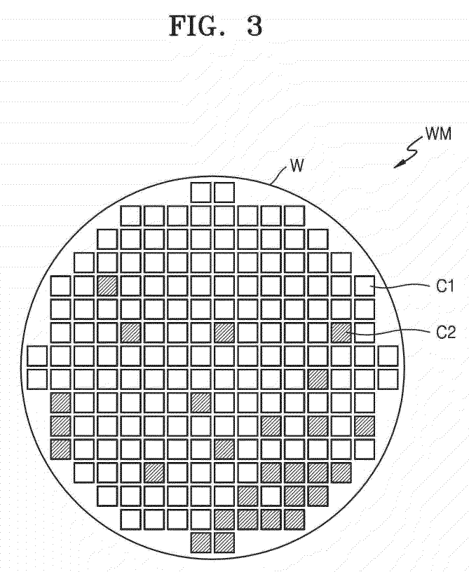

FIG. 2 is a flowchart illustrating a method of analyzing a wafer map according to some example embodiments, and FIG. 3 is a view illustrating a wafer map according to some example embodiments.

Referring to FIG. 2, the method of analyzing a wafer map may include operations S10 and S20.

In operation S10, a deep learning model (e.g., a neural network model) MD may be created using a first wafer map WM1. In some example embodiments, the deep learning model MD may be created in the neural network device 13 of FIG. 1. The first wafer map WM1 may refer to image data used to create the deep learning model MD in the neural network device 13. The first wafer map WM1 may be created using raw data stored in the memory 12 of FIG. 1.

In operation S20, a second wafer map WM2 may be analyzed using the deep learning model MD. The deep learning model MD may be, e.g., applied to the analysis device 14 of FIG. 1. The second wafer map WM2 may refer to image data to be analyzed. The second wafer map WM2 may be created using data measured (e.g., newly and/or otherwise measured) during a process of manufacturing a semiconductor device.

Referring to FIG. 3, a wafer W may be, e.g., a semiconductor substrate used in the process of manufacturing a semiconductor device, and the semiconductor device (e.g., a transistor) may be formed on a surface of the wafer W. In some example embodiments, for example, the semiconductor substrate may be, and/or include a silicon. The wafer W, which is a processed wafer (e.g., “fab-out”), may be diced into a plurality of units C1 and C2 so as to be separated in a subsequent process. The units C1 and C2 may be configured in a chip unit, but is not limited thereto, and the units C1 and C2 may be configured in various units such as a block and a shot.

Raw data may be extracted in units of the wafer W. For example, in some example embodiments, raw data may be extracted from each of the units C1 and C2 of the wafer W. In order to detect a defect in the wafer W, various tests may be performed on the units C1 and C2, and the raw data may be data including a result of the tests.

The tests may include, e.g., an electrical test for verifying a short circuit, a leakage current, an operating time of a transistor formed on the wafer W, and/or the like. Accordingly, the raw data may represent electrical characteristics of each of the units C1 and C2. The raw data may be acquired in units of wafers W.

A wafer map WM may be an image in which electrical characteristics are displayed for each of the units C1 and C2 in a plan view of the wafer W based on raw data. For example, the wafer map WM may be an image to which raw data is mapped. In some example embodiments, the units C1 and C2 may be divided into, e.g., good units C1 and bad units C2. A good unit C1 may refer to a unit with good characteristics, and a bad unit C2 may refer to a unit with bad characteristics. For example, the good unit C1 may include a unit having an electrical characteristic equal to or greater than a threshold value, and the bad unit C2 may include a unit having an electrical characteristic less than the threshold value. The good unit C1 and the bad unit C2 may be expressed with different fill shapes, brightness, saturation, and/or color, but the example embodiments are not limited thereto. For example, in other example embodiments, the wafer maps WM1 and WM2 may be expressed in a manner other than fill shapes, brightness, saturation, or color.

In the wafer map WM, the units of the wafer W are classified into the good unit C1 and the bad unit C2, but are not limited thereto, and the units C1 and C2 may be divided into three or more stages. For example, in some example embodiments, the units C1 and C2 may be expressed in 5 different levels of fill shapes, brightness, saturation, and/or color. The wafer map WM may be expressed as a continuous value rather than a discrete value. In this case, the wafer map WM may be continuously expressed for each of the units C1 and C2 using fill shapes, brightness, saturation, color, and/or other methods.

In some example embodiments, the raw data may be divided into first raw data RD1 and second raw data RD2. The first raw data RD1 may be data used to create the deep learning model MD, and the second raw data RD2 may be data to be analyzed using the deep learning model MD. For example, the first raw data RD1 may be data for a test, and the second raw data RD2 may be data extracted during the process of manufacturing the semiconductor device. The first raw data RD1 may be data stored in the memory 12, and the second raw data RD2 may be (e.g., newly) measured data.

Hereinafter, the wafer map WM may be described as being divided into the first wafer map WM1 and the second wafer map WM2. The first wafer map WM1 may be image data created based on the first raw data RD1, and the second wafer map WM2 may be image data created based on the second raw data RD2. The first wafer map WM1 may be a wafer map used to create the deep learning model MD in the neural network device 13, and the second wafer map WM2 may be a wafer map analyzed using the deep learning model MD in the analysis device 14.

Hereinafter, for convenience of description, raw data may refer to a set of a plurality of pieces of raw data extracted from each of a plurality of wafers. Accordingly, the first raw data RD1 may refer to a set of a plurality of pieces of raw data used to create the deep learning model MD, and the second raw data RD2 may refer to a set of a plurality of pieces of raw data analyzed using the deep learning model MD. Also, the first wafer map WM1 created based on the first raw data RD1 may refer to a set of a plurality of wafer maps used in the neural network device 13, and the second wafer map WM2 created based on the second raw data RD2 may refer to a set of wafer maps analyzed by the analysis device 14.

Hereinafter, operations S10 and S20 of FIG. 2 are described in detail.

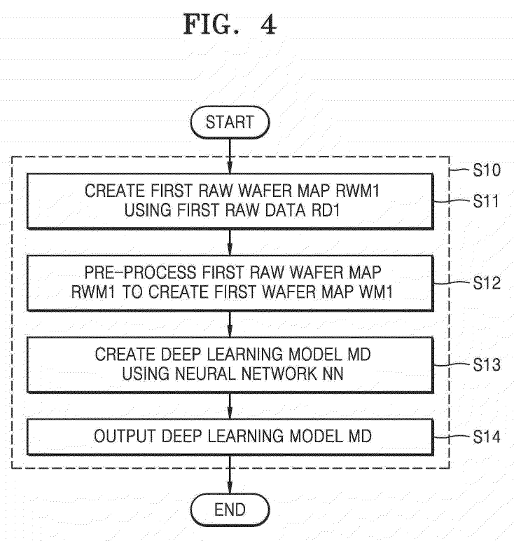

FIG. 4 is a flowchart illustrating a method of analyzing a wafer map according to some example embodiments. In some example embodiments, FIG. 4 is a view illustrating operation S10 of FIG. 2, and is described with reference to FIGS. 1 to 3.

Referring to FIG. 4, the wafer map analysis method may include operation S10 of creating a deep learning model MD using the first wafer map WM1, and operation S10 may include operations S11, S12, S13, and S14.

In operation S11, a first raw wafer map RWM1 may be created using the first raw data RD1. The first raw data RD1 may be data stored in the memory 12. The first raw data RD1 may include data measured during the process of manufacturing the semiconductor device, and may include data accumulated over a long period of time.

The first raw data RD1 may be input to the first pre-processing device 15-1. The first pre-processing device 15-1 may convert the first raw data RD1 into a first raw wafer map RWM1 (e.g., image data). The first raw wafer map RWM1 may refer to a wafer map that is not pre-processed after the first raw data RD1 is converted, or may refer to a wafer map in which a portion of pre-processing is performed after the first raw data RD1 is converted.

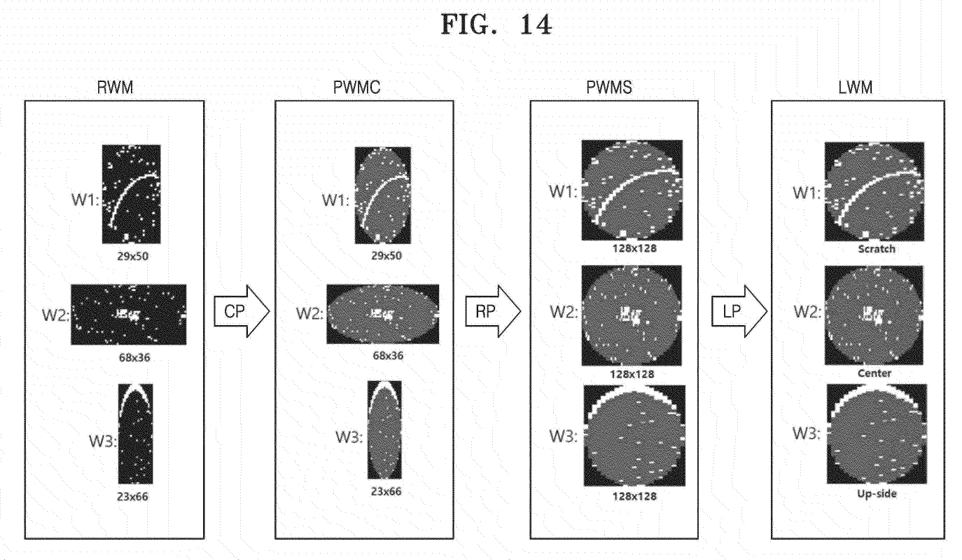

In operation S12, the first pre-processing device 15-1 may create the first wafer map WM1 by pre-processing the first raw wafer map RWM1. For example, the first raw wafer map RWM1 may be a wafer map on which at least one of a channel expansion process, a resizing process, a labeling process, a virtual wafer map additional creation process, and/or a classification process, which are described below with reference to FIGS. 14 to 16, is performed.

The first pre-processing device 15-1 may be included in the neural network device 13. The first pre-processing device 15-1 may perform the channel expansion process, the resizing process, the labeling process, the virtual wafer map additional creation process, the classification process, and/or the like. The first pre-processing device 15-1 may create the first wafer map WM1 by processing (or, alternatively, pre-processing) the first raw wafer map RWM1, and provide the first wafer map WM1 to the neural network device 13. By processing the first raw wafer map RWM1 in the first pre-processing device 15-1, a learning speed of the deep learning model MD using the neural network NN in operation S13 may be increased, and the deep learning model MD may output an accurate result.

In operation S13, the neural network device 13 may receive the first wafer map WM1, and the first wafer map WM1 may be used to create the deep learning model MD. For example, the first wafer map WM1 may be, and/or include, data for learning and/or verifying the deep learning model MD. The neural network device 13 may create the deep learning model MD that has learned a defect pattern of the first wafer map WM1 using the neural network NN.

The neural network NN may refer to a deep learning module that performs a certain operation, such as image classification, through learning. For example, the neural network NN may include at least one of various types of neural network models such as a CNN, a R-CNN, an RPN, an RNN, an S-DNN, an S-SDNN, a DBN, an RBM, a fully convolutional network, an LSTM network, a classification network, a GRU, a SNN, a GAN, etc. A neural network NN used in some example embodiments is described in detail with reference to FIGS. 7 to 13 to be described below.

The neural network device 13 may train the deep learning model MD using the first wafer map WM1. The trained deep learning model MD may analyze and verify a defect type of the first wafer map WM1. The deep learning model MD may be updated, e.g., through updates and/or relearning.

In operation S14, the neural network device 13 may output the deep learning model MD. For example, the deep learning model MD output from the neural network device 13 may be stored in the memory 12.

Hereinafter, operation S13 is described in more detail.

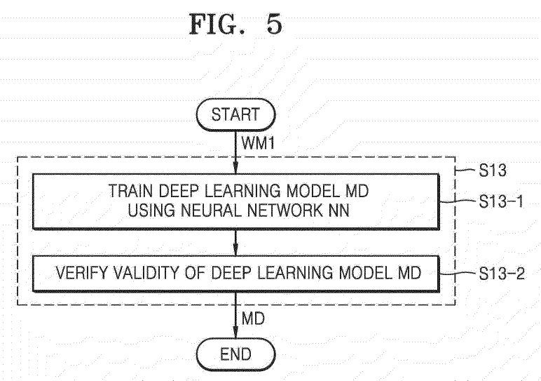

FIG. 5 is a flowchart illustrating a method of analyzing a wafer map according to some example embodiments. In some embodiments, FIG. 5 is a view illustrating operation S13 of FIG. 4, and is described with reference to FIGS. 1 to 4.

Referring to FIG. 5, operation S13 may include operations S13-1 and S13-2. The first wafer map WM1 used in operation S13 may be a wafer map classified into a plurality of datasets through operation S12.

The dataset may refer to a set of wafer maps used in the neural network device 13. For example, the first wafer map WM1 may be classified into a training dataset, a validation dataset, and/or a test dataset. The training dataset may be a set of wafer maps used for training the deep learning model MD in operation S13-1, the verification dataset may be a set of wafer maps used to verify performance of the deep learning model MD being trained in operation S13-1, and the test dataset may be a set of wafer maps used to verify the performance of the deep learning model MD after the training of the deep learning model MD is finished in operation S13-2. However, the example embodiments are not limited thereto, and in other embodiments, the first wafer map WM1 may not be divided into a plurality of datasets and/or may be divided into four or more datasets.

In operation S13-1, the neural network device 13 may train the deep learning model MD using the neural network NN. For training, the first wafer map WM1 included in the training dataset may be used. The first wafer map WM1 included in the training dataset may be a wafer map on which the labeling process is performed in operation S12. The deep learning model MD may analyze and classify an input image through learning. As the deep learning model MD learns better, the classification performance for accurately classifying the input image may be improved.

Operation S13-1 may be performed until, e.g., a first verification is completed. The first verification may be performed to determine a training progress of the deep learning model MD in operation S13-1. The first verification may be performed using the first wafer map WM1 included in the verification dataset.

When performing the first verification, the neural network device 13 may use indicators such as loss and accuracy to determine the progress of training using the neural network NN. For example, if the loss converges close to, e.g., 0% and the accuracy converges close to, e.g., 100% as a result of performing the first verification, it may be considered to be determined that the deep learning model MD accurately classifies the defect type of the first wafer map WM1. The neural network device 13 may terminate operation S13-1 when it is determined that the deep learning model MD is suitable through the first verification.

In operation S13-2, a second verification may be performed. For example, the neural network device 13 may check and evaluate, e.g., a final (e.g., a latest) performance of the deep learning model MD by validating the validity of the learned deep learning model MD. The second verification may be performed by inputting the unlabeled first wafer map WM1 to the deep learning model MD determined to be suitable through the first verification. The second verification may be performed using the first wafer map WM1 included in the test dataset.

When performing the second verification, the neural network device 13 may use indicators such as accuracy, recall, precision, confusion matrix, F1 score, etc. to determine the performance of the deep learning model MD. In operation S40, the neural network device 13 may output a deep learning model MD of which the performance is verified through the second verification.

According to some example embodiments, the deep learning model MD may efficiently classify wafer maps according to defect types by learning the pattern of the wafer maps using the neural network NN.

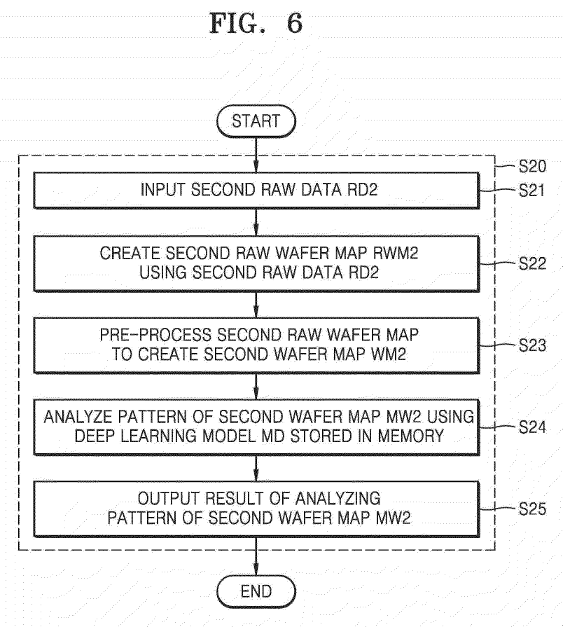

FIG. 6 is a flowchart illustrating a method of analyzing a wafer map according to some example embodiments. In some example embodiments, FIG. 6 is a view illustrating operation S20 of FIG. 2, and is described with reference to FIGS. 1 to 4.

Referring to FIG. 6, the method of analyzing a wafer map may include operation S20 of analyzing a pattern of the second wafer map WM2 using the deep learning model MD, and operation S20 may include operations S21, S22, S23, S24, and S25.

In operation S21, the second raw data RD2 may be input to the second pre-processing device 15-2. The second raw data RD2 may be data to be analyzed. For example, unlike the first raw data RD1, the second raw data RD2 may be data measured during the process of manufacturing the semiconductor device. The data measured during the manufacturing the semiconductor device may be referred to as newly measured data. For example, the second raw data RD2 may be considered new compared to at least one of the data included in the first raw data RD1. According to some embodiments, the second raw data RD2 may be stored in the memory 12 after operation S25 is performed, so as to be used as the first raw data RD1.

In operation S22, the second pre-processing device 15-2 may convert the second raw data RD2 into a second raw wafer map RWM2 (e.g., image data). The second raw wafer map RWM2 may refer to a wafer map that is not pre-processed after the second raw data RD2 is converted and/or a wafer map in which a portion of the pre-processing is performed after the second raw data RD2 is converted.

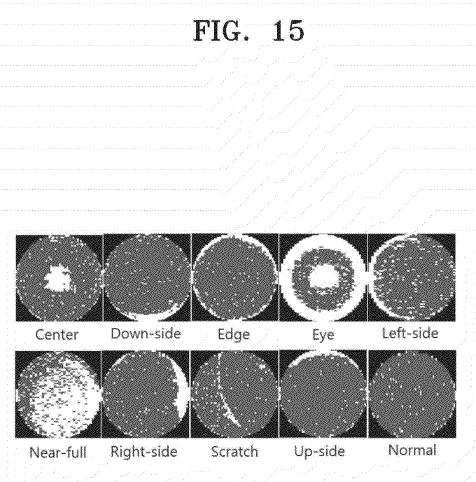

In operation S23, the second pre-processing device 15-2 may process (e.g., pre-process) the second raw wafer map RWM2 to create the second wafer map WM2. For example, the second wafer map WM2 may be a wafer map obtained by performing at least one of the channel expansion process and the resizing process, which are described below with reference to FIGS. 14 and 15, on the second raw wafer map RWM2.

The processing performed by the second pre-processing device 15-2 may be different from the processing performed by the first pre-processing device 15-1. For example, the second pre-processing device 15-2 may perform at least one of the channel expansion process and/or the resizing process; and/or, for example, the second pre-processing device 15-2 may not perform the labeling process, the virtual wafer map additional creation process, and/or the classification process. The second pre-processing device 15-2 may create the second wafer map WM2 by pre-processing the second raw wafer map RWM2, and provide the second wafer map WM2 to the analysis device 14. By performing pre-processing on the second raw wafer map RWM2 by the second pre-processing device 15-2, the second wafer map WM2 may be applied to the deep learning model MD created through the neural network device 13.

In operation S24, the analysis device 14 may analyze a pattern of the second wafer map WM2 using the deep learning model MD created by the neural network device 13 in operation S10. For example, the second wafer map WM2 may be applied to the verified deep learning model MD.

By analyzing the pattern of the second wafer map WM2, the deep learning model MD may determine a defect type of the second wafer map WN2. For example, the defect type may be among defect types of the wafer maps described below with reference to FIG. 15. The deep learning model MD updated with the new defect type may analyze the second wafer map WM2 including the updated defect type

In operation S25, the analysis device 14 may output information on the second wafer map WM2. The analysis device 14 may output a pattern analysis result of the second wafer map WM2 determined through the deep learning model MD (e.g., a defect type of the second wafer map WM2).

For example, the analysis device 14 may designate a label for the pattern analysis result of the second wafer map WM2 and may output data of the corresponding label and data related to the corresponding label. For example, the analysis device 14 may store the data of the corresponding label and the data related to the corresponding label (e.g., raw data RD) in a file. The data of the corresponding label and the data related to the corresponding label may be used to analyze a defect in a process and/or a defect in a manufacturing facility of the semiconductor device formed on a wafer.

FIG. 7 is a view illustrating a structure of a neural network according to some example embodiments. In some example embodiments, FIG. 7 is a diagram showing a structure of the neural network NN used in, e.g., operation S13 of FIG. 4.

Referring to FIG. 7, the neural network NN may include a plurality of layers. For convenience of description, a set of the layers may be referred to as a “module.” In some example embodiments, the neural network NN may include a plurality of modules M1, M2, and M3. In some example embodiments, a first module M1 may include layers having a relatively shallower depth than a second module M2, and/or the second module M2 may include layers having a relatively shallower depth than a third module M3. For example, the modules M1, M2, and M3 may be classified based on the second module M2. For example, layers positioned before the second module M2 may be referred to as the first module M1, and layers positioned after the second module M2 may be referred to as the third module M3.

Each of the modules M1, M2, and M3 may include a plurality of layers, and in some example embodiments, may include at least one of a linear layer and a non-linear layer. The linear layer may include a convolutional layer, a fully-connected layer, a global average pooling (GAP) layer, a softmax layer, etc., and the non-linear layer may include a pooling layer and/or the like. According to some example embodiments, at least one linear layer and at least one non-linear layer may be combined to be referred to as one layer. For example, an inception layer may include a plurality of convolutional layers and at least one pooling layer.

Each of layers may receive an image and/or feature map output from a previous layer and may output a new image and/or feature map by calculating the received image and/or feature map. The feature map may be data in which various features of an image input to each of the plurality of layers are expressed. The feature map may have a two-dimensional (2D) matrix and/or a three-dimensional (3D) matrix (and/or tensor) structure. The feature map may include at least one channel in which feature values are arranged in a matrix. When the feature map has a plurality of channels, the plurality of channels may have the same number of rows and columns.

The first module M1 may receive the first wafer map WM1. The first module M1 may extract meaningful characteristic information (e.g., significant characteristic information) from the first wafer map WM1 and perform sub sampling. The first module M1 may create a first output feature map FM1 based on meaningful characteristic information of the first wafer map WM1. For example, the meaningful characteristic information may include information related to and/or selected based on a relation to a type, location, rate, etc. of defect(s).

The second module M2 may be between the first module M1 and the third module M3. The second module M2 may receive the first output feature map FM1. The second module M2 may include an inception module, and the inception module may include a plurality of inception layers. For example, the inception module may include two inception layers. The inception module may, e.g., include a first inception layer IL1 and a second inception layer IL2 that are sequentially arranged.

The second module M2 may further include a shortcut connection. The shortcut connection may skip the inception module. The shortcut connection may connect the first output feature map FM1 to a layer output from the inception module (hereinafter, referred to as a ‘final output inception layer’). Accordingly, an addition operation may be performed on the first output feature map FM1 and the final output inception layer.

The significant characteristic information may be extracted from the first output feature map FM1 through the second module M2 and sub-sampling may be performed. The second module M2 may efficiently learn a deep and wide network by including a plurality of inception layers. For example, by learning using the second module M2, learning performance may be increased and the amount of computations may be reduced. The second module M2 may create a second output feature map FM2 as an addition operation is performed on the first output feature map FM1 and a final output inception layer.

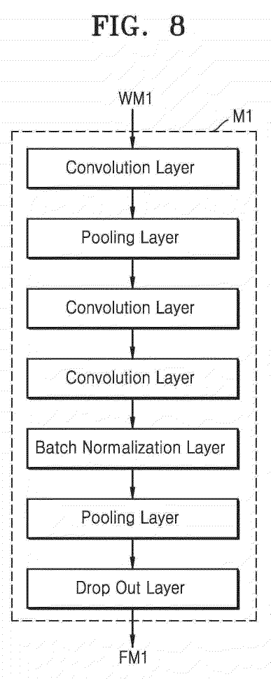

The third module M3 may receive the second output feature map FM2. The third module M3 may analyze a pattern of the first wafer map WM1 based on the second output feature map FM2 and may determine a defect type of the first wafer map WM1. The third module M3 may include, e.g., a GAP layer. In the case wherein the third module M3 includes the GAP layer, overfitting may be improved. The third module M3 may output a pattern analysis result AR of the first wafer map WM1.

[100] Hereinafter, the modules M1, M2, and M3 are described with reference to FIGS. 8 to 13.

FIG. 8 is a view illustrating the structure of the first module M1 according to some example embodiments. In some example embodiments, FIG. 8 is a view illustrating a structure of the first module M1 of FIG. 7.

Referring to FIG. 8, the first module M1 may include at least one convolutional layer and at least one pooling layer. For example, the first module M1 may include three convolutional layers and two pooling layers. The first module M1 may further include a batch normalization layer and/or a dropout layer. For example, three convolutional layers, two pooling layers, one batch normalization layer, and one dropout layer may be positioned as shown in FIG. 8.

The first wafer map WM1 may be input to the first module M1. For example, the first wafer map WM1 and/or a feature map output from another layer may be input to the convolutional layer. The convolution layer may extract meaningful characteristic information from the input data. In some example embodiments, the convolution layer may be, e.g., iteratively trained in order to identify characteristic information of the first wafer map WM1.

The pooling layer may perform sub-sampling to reduce characteristic information included in the input feature map. The pooling layer may change a spatial size of the input feature map. The pooling layer may include a max pooling layer. For example, at least one of the pooling layer may refer to a max pooling layer.

The batch normalization layer may be adjusted so that a deformed distribution does not occur during the training process of the deep learning model. For example, the batch normalization layer may normalize the input feature map using a mini-batch as a unit. The batch normalization layer may perform normalization using the mean and variance. By using the batch normalization layer, a gradient vanishing phenomenon, and/or a gradient exploding phenomenon may be improved. In addition, overfitting may be improved, and as dependence on selection of an initial weight value decreases, a learning speed may increase and the deep learning model MD may be trained stably.

The dropout layer may omit some neurons of the input feature map. Accordingly, the deep learning model may be trained through the reduced neural network. The dropout layer may randomly omit some neurons. Over-fitting may be improved using the dropout layer.

The first module M1 illustrated in FIG. 8 is an example of a neural network model for recognizing a defect pattern, but the example embodiments are not limited thereto, and a structure of the first module M1 may be variously changed according to the embodiments. For example, the first module M1 may have a different structure according to a type of the wafer and a type of the defect pattern as a target. For example, according to some example embodiments, the batch normalization layer included in the first module M1 may be positioned before the convolution layer, and/or the dropout layer may be omitted or replaced with the batch normalization layer.

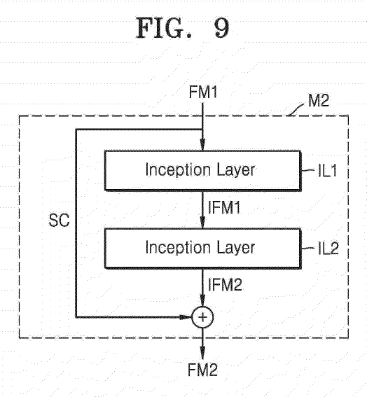

FIG. 9 is a view illustrating a structure of the second module M2 according to some example embodiments. In some example embodiments, FIG. 9 is a view illustrating the structure of the second module M2 of FIG. 7.

Referring to FIG. 9, the second module M2 may include a plurality of inception layers. The plurality of inception layers may be sequentially arranged. The sequentially arranged inception layers may be referred to as an ‘inception module’. For example, the second module M2 may include a first inception layer IL1 and a second inception layer IL2. Accordingly, the sequentially arranged first inception layer IL1 and second inception layer IL2 may be referred to as an ‘inception module’. Each of the inception layers may include a plurality of layers, some of which perform operations in parallel. Hereinafter, a case in which the inception module includes two inception layers is described, but the example embodiments are not limited thereto. For example, the inception module may include three or more inception layers.

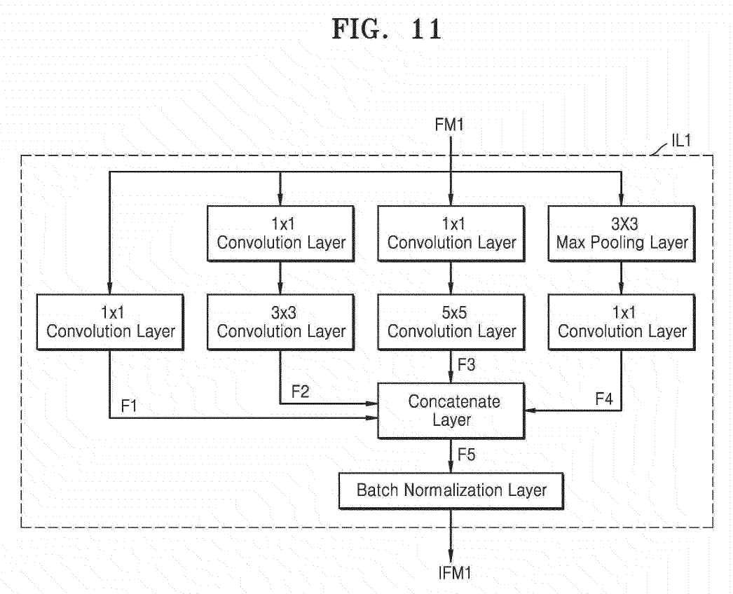

A first inception layer IL1 may receive a first output feature map FM1 output from the first module M1, and may output a first inception output feature map IFM1. The second inception layer IL2 may receive a first inception output feature map IFM1 and output a second inception output feature map IFM2. The second inception output feature map IFM2 may be a final output feature map of the inception module. For example, in some example embodiments, the second inception output feature map IFM2 may be referred to as a “final inception output feature map.” In some example embodiments, the first inception layer IL1 and the second inception layer IL2 may have the same structure. The structures of the first inception layer IL1 and the second inception layer IL2 are described in detail with reference to FIG. 11 to be described below.

The second module M2 may include a shortcut connection SC. The second module M2 may be realized by a feed-forward neural network having the shortcut connection SC. When the second module M2 includes two inception layers and the shortcut connection SC, the second module M2 may be positioned as shown in FIG. 9, but the example embodiments are not limited thereto.

The shortcut connection SC may skip one or more layers. The shortcut connection SC may skip the inception module. For example, the shortcut connection SC may skip the first inception layer IL1 and the second inception layer IL2. The shortcut connection SC may connect the first output feature map FM1 to a final inception output feature map that is an output feature map of the inception module. For example, the shortcut connection SC may connect the first output feature map FM1 to the second inception output feature map IFM2 that is the final inception output feature map. The second module M2 may perform an addition operation on the second inception output feature map IFM2 that is the final inception output feature map and the first output feature map FM. Accordingly, the second output feature map FM2 may be output from the second module M2.

The example embodiments may include the inception modules IL1 and IL2 and the shortcut connection SC, thereby increasing computational efficiency and improving the performance of the deep learning model. The example embodiments may increase a learning rate of the deep learning model for analyzing a wafer map and/or improve the gradient vanishing through the first inception layer IL1, the second inception layer IL2, and the shortcut connection SC. Accordingly, a deep learning model suitable for a semiconductor manufacturing environment may be implemented, and the pattern of the wafer map may be analyzed efficiently.

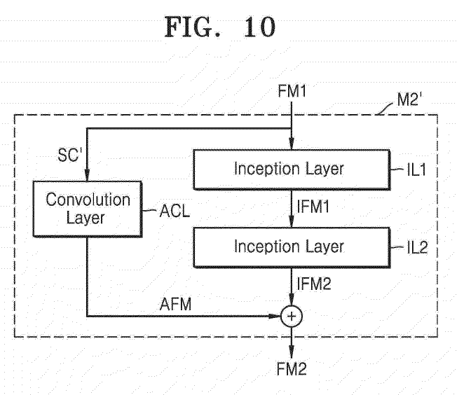

FIG. 10 is a view illustrating a structure of the second module M2 according to some example embodiments. In some example embodiments, FIG. 10 is another embodiment of FIG. 9 and is a view illustrating another structure (e.g., a second module M2') of the second module M2 of FIG. 7.

Referring to FIG. 10, the second module M2' may further include at least one additional convolutional layer. Although the present embodiment illustrates a case in which one additional convolutional layer ACL is included, the example embodiments are not limited thereto. For example, a plurality of additional convolutional layers may be further included and/or a pooling layer may be further included. For example, the additional convolution layer ACL may perform convolution using any one of a 1X1 size filter, a 3X3 size filter, and a 5X5 size filter. According to some example embodiments, the structure of the additional convolutional layer ACL may be variously changed.

Shortcut connection SC' and the additional convolutional layers ACL may skip the inception module. For example, the shortcut connection SC' and the additional convolution layer ACL may perform operations in parallel with the inception module. For example, the shortcut connection SC' and the additional convolutional layer ACL may perform operations in parallel with the first inception layer IL1 and the second inception layer IL2 included in the inception module by skipping the first inception layer IL1 and the second inception layer IL2.

For example, in some example embodiments, the shortcut connection SC' may be connected to the additional convolutional layer ACL. The additional convolutional layer ACL may receive the first output feature map FM1 through the shortcut connection SC'. The additional convolutional layer ACL may create an additional output feature map AFM based on the first output feature map FM1. The second module M2' may create the second output feature map FM2 by performing an addition operation on the additional output feature map AFM and the final inception output feature map. For example, in some example embodiments, the second module M2' may generate the second output feature map FM2 by performing an addition operation on the additional output feature map AFM and the second inception output feature map IFM2.

Hereinafter, the inception layer of the second module M2 is described in detail.

FIG. 11 is a view illustrating a structure of an inception layer according to example embodiments of the inventive concept. In an embodiment, FIG. 11 is a view illustrating the structure of each of the inception layers described above with reference to FIGS. 9 and 10. The inception layers may have the same structure, and thus, the first inception layer IL1 is described below. Hereinafter, descriptions thereof are made with reference to FIG. 9.

Referring to FIG. 11, the first inception layer IL1 may include a plurality of layers. At least some of the layers may perform operations in parallel.

The first inception layer IL1 may include a plurality of convolutional layers and at least one pooling layer. For example, the first inception layer IL1 may include six convolutional layers and one pooling layer. The convolutional layers may perform convolution with filters having different sizes. For example, each of the convolutional layers may perform convolution using any one of the 1X1 size filter, the 3X3 size filter, and/or the 5X5 size filter.

For example, the first inception layer IL1 may perform convolution with the 1X1 size filter before performing convolution with the 3X3 size filter or the 5X5 size filter. Accordingly, the amount of computations may be reduced. The convolutional layer using the 1X1- sized filter may receive the first output feature map FM1 and/or a feature map output from a pooling layer which has received the first output feature map FM1. In some example embodiments, the pooling layer may refer to a max pooling layer.

Some layers included in the first inception layer IL1 may perform operations in parallel. At least a portion of the first inception layer IL1 may perform a computation using the convolutional layers that perform operations in parallel. For example, each of the convolutional layers may perform an operation in parallel using any one of the 1X1 size filter, the 3X3 size filter, and the 5X5 size filter. For example, a convolution operation through the convolutional layer and a subsampling operation through the pooling layer may be simultaneously performed. As the first inception layer IL1 performs operations in parallel, computational efficiency may be improved and various features of an image may be extracted.

The first inception layer IL1 may further include a concatenate layer (e.g., a connection layer). The concatenate layer may combine at least two of a plurality of output feature maps created as a result of the computation into one feature map. For example, the concatenate layer may receive a plurality of output feature maps F1, F2, F3, and F4 created as computations are performed in parallel, and may combine the output feature maps as a single feature map, and output the single feature map. For example, the concatenate layer may receive at least two of the output feature maps F1, F2, F3, and F4 output from the convolutional layers and then combine the feature maps into one feature map. For example, the concatenate layer may combine the output feature maps F1 and F4 of the convolution layer using the 1X1 size filter, the output feature map F2 of the convolution layer using the 3X3 size filter, and the output feature map F3 of the convolution layer using the 5X5 size filter into a single feature map and output the single feature map.

The first inception layer IL1 may further include the batch normalization layer. The batch normalization layer may receive an output feature map F5 of the concatenate layer as an input feature map. The batch normalization layer may use mean and variance to speed up learning and stabilize learning. In addition, because the inception layer IL1 further includes the batch normalization layer, overfitting may be improved. The first inception output feature map IFM1, which is an output feature map of the batch normalization layer, may be input to the second inception layer IL2.

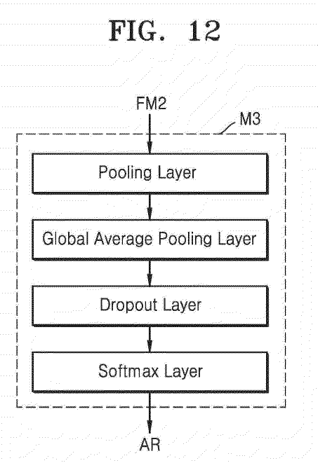

FIG. 12 is a view illustrating a structure of the third module M3 according to some example embodiments. In some example embodiments, FIG. 12 is a view illustrating a structure of the third module M3 of FIG. 7.

Referring to FIG. 12, the third module M3 may include at least one of the pooling layer, the fully-connected layer (not shown), the GAP layer, the dropout layer, and/or the soft max layer. For example, the third module M3 may include one pooling layer, one GAP layer, one dropout layer, and one soft max layer. For example, the third module M3 may have a structure as shown in FIG. 8, but the example embodiments are not limited thereto. In some example embodiments, the pooling layer may be a max pooling layer.

The GAP layer may classify the feature information extracted through the pooling layer and/or the convolutional layer. In some example embodiments, the GAP layer may classify the characteristic information extracted through the pooling layer. For example, the GAP layer may output a computation result for a possibility that the input data is classified as each defect type. By using the GAP layer, the computation performed in the third module M3 may be reduced, and an overfitting phenomenon may be improved.

The soft max layer may probabilistically calculate which type of defect pattern the classified characteristic information belongs to. For example, the soft max layer may output a probability value obtained by normalizing a result value of the possibility that the input data is classified as each defect pattern. The neural network device 13 may analyze a pattern of the wafer map based on the probability value calculated through the soft max layer and determine which defect type the wafer map corresponds to.

The third module M3 shown in FIG. 12 is only an example of the third module M3 for classifying the defect pattern, and the structure of the third module M3 used for analyzing the defect pattern is not limited thereto.

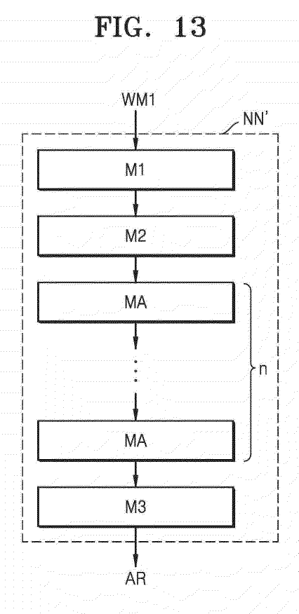

FIG. 13 is a view illustrating a structure of a neural network according to some example embodiments. In some example embodiments, FIG. 13 is a view showing another embodiment (e.g., a neural network NN') of FIGS. 6 and 7. Accordingly, the same reference numerals as those of FIG. 7 may refer to the same components. Hereinafter, descriptions thereof are made with reference to FIG. 7.

Referring to FIG. 13, the neural network NN' may further include n additional modules MA. For example, n may be an integer of 1 or greater. The additional module MA may have the same structure as that of the second module M2 described above with reference to FIGS. 9 to 11. For example, the additional module MA may include a plurality of inception layers and a shortcut connection that skips the plurality of inception layers. For example, the additional module MA may include two inception layers and a shortcut connection that skips the two inception layers. For example, the neural network NN’ may have a structure including n+1 second modules M2. In some example embodiments, an (n)^{th} additional module among a plurality of additional modules may receive an output feature map of at least one of the second module and a previous additional module among the plurality of additional modules, and may output an (n)^{th} additional output feature map based on the received output feature map.

The n additional modules may be sequentially arranged between the second module M2 and the third module M3. For example, the neural network NN' may have a structure in which n+1 second modules M2 are sequentially arranged between the first module M1 and the third module M3. Accordingly, the third module M3 may determine a defect type of the first wafer map WM1 based on the nth additional output feature map output from the nth additional module among the n additional modules.

In some example embodiments, the classification performance of the deep learning model MD may be improved by including n additional modules MA between the second module M2 and the third module M3.

FIG. 14 is a view illustrating processing according to some example embodiments, and FIG. 15 is a view illustrating a label according to a defect type of a wafer map. In some example embodiments, FIG. 14 is a view illustrating the processing described above in operation S12 of FIG. 4 and operation S23 of FIG. 6, and FIG. 15 is a view illustrating a label used in the labeling process of FIG. 6. Hereinafter, descriptions thereof are made with reference to FIGS. 1 to 6.

Referring to FIG. 14, a raw wafer map RWM may be prepared. The raw wafer map RWM may refer to a wafer map that has not been processed (e.g., pre-processed) after having been converted from raw data and/or a wafer map on which a portion of the processing (e.g., pre-processing) has been performed, but for convenience of description, the wafer map that has not been processed after having been converted from raw data may be referred to as the raw wafer map RWM. Accordingly, in FIG. 14, a channel-extended raw wafer map RWM may be referred to as a ‘channel processed wafer map PWMC’, a resized raw wafer map RWM may be referred to as a ‘resized wafer map PWMS’, and a labeled raw wafer map RWM may be referred to as a ‘labeled wafer map LWM’.

In the present example embodiments, a case in which a channel expansion process CP, a resizing process RP, and a labeling process LP are sequentially performed on the raw wafer map RWM is described, but the example embodiments are not limited thereto. For example, at least one of the channel expansion process CP, the resizing process RP, and the labeling process LP may be omitted in the processing. Accordingly, a raw wafer map RWM that is not the channel processed wafer map PWMC may be resized, or a raw wafer map RWM that is not the resized wafer map PWMS may be labeled.

The raw wafer map RWM may have different sizes depending on the type of the semiconductor device formed on the wafer W, the sizes of units U1 and U2 of the wafer on which a test is performed, a type of a test device for testing the wafer, etc. For example, a raw wafer map of a first wafer W1 may have dimensions of 29 pixels horizontally and 50 pixels vertically, a raw wafer map of a second wafer W2 may have dimensions of 68 pixels horizontally and 36 pixels vertically, and a raw wafer map of a third wafer W3 may have dimensions of 23 pixels horizontally and 66 pixels vertically.

The raw wafer map RWM may be expressed in gray scale in which the outline of the wafer W is not displayed. For example, the raw wafer map RWM may have one channel or two channels. Accordingly, the outline of the wafer may not be displayed on the raw wafer map RWM. Therefore, processing (e.g., the pre-processing) for the raw wafer map RWM may improve the learning ability of the deep learning model MD. For example, the wafer map WM may be an image in which the raw wafer map RWM is converted into a form that may be processed by the neural network NN.

The processing may include a channel expansion process CP to expand channels of the raw wafer map RWM, a resizing process RP to change a size of the raw wafer map RWM, a labeling process LP to label the raw wafer map RWM, a virtual wafer map additional creation process to additionally create a virtual wafer map, and/or a classification process to classify the wafer maps into a plurality of datasets.

The -processing order may be variously changed. For example, the processing may be performed in the order of the resizing process RP and the channel expansion process CP. Alternatively, the processing may be performed in the order of the channel expansion process CP, the resizing process RP, the labeling process LP, and/or the virtual wafer map creation process.

The channel expansion process CP may expand channels of the raw wafer map RWM. For example, the channels of the raw wafer map RWM may be expanded from two to three. The raw wafer map RWM may be processed to have a three-channel image matrix. The three channels may include a red channel, a green channel, and a blue channel. As the channels of the raw wafer map RWM are expanded, the outline of the wafer W may be revealed in the channel processed wafer map PWMC. In the channel processed wafer map PWMC, portions other than the wafer may be displayed in black.

The resizing process RP may resize the channel processed wafer map PWMC. A size of the resized wafer map PWMS may be variously set. For example, the size of the resized wafer map PWMS may be set to 128 pixels horizontally and 128 pixels vertically. Accordingly, the resized wafer map PWMS of the first to third wafers W1, W2, and W3 may all have a size of 128 pixels horizontally and 128 pixels vertically.

The labeling process LP may label the resized wafer map PWMS according to the pattern of the wafer map. The label may define defect types according to patterns of the wafer map. For example, the wafer map WM classified as the first type may be labeled as the first type.

Referring to FIG. 15, a label may be designated to be different according to a pattern of the channel processed wafer map PWMC. For example, the label may be designated to any one of center, down-side, edge, eye, left-side, near-full, light-side, scratch, up-side, normal, and/or the like. When a new defect pattern is to be added, a new label may be assigned to the wafer map WM having the new defect pattern.

For example, the labeled wafer map LWM of the first wafer W1 may be labeled as ‘scratch’, the labeled wafer map LWM of the second wafer W2 may be labeled as ‘center’, the labeled wafer map LWM of the third wafer W3 may be labeled as ‘up-side’. When a new defect pattern is added, the deep learning model MD may be updated in operation S30 using the wafer map LWM labeled with a new label.

The classification process may classify the raw wafer map RWM into a plurality of datasets. The dataset may refer to a set of wafer maps. For example, the wafer map may be classified as any one of a training dataset used to train the deep learning model MD, a validation dataset used to verify performance of the deep learning model MD while the deep learning model is being trained, and a test dataset used to verify the performance of the deep learning model MD after the training of the deep learning model MD is finished. However, the example embodiments are not limited thereto, and in other embodiments, the wafer maps may not be classified into a plurality of datasets and/or may be classified as four or more datasets.

The classification process may randomly classify the raw wafer map RWM into any one of the training dataset, the validation dataset, and the test dataset. The training dataset, the verification dataset, and the test dataset may include different numbers of wafer maps. For example, the largest number of wafer maps may be included in the training dataset.

The processing may be performed in, e.g., the first pre-processing device 15-1 and/or the second pre-processing device 15-2. For example, the first pre-processing device 15-1 may perform the processing on the first raw wafer map RWM1 created based on the first raw data RD1, and the second pre-processing device 15-2 may perform the processing on the second raw wafer map RWM2 created based on the second raw data RD2. The first pre-processing device 15-1 and the second pre-processing device 15-2 may perform different processing techniques. For example, the first pre-processing device 15-1 may perform all of the channel expansion process CP, the resizing process RP, the labeling process LP, the classification process, and the virtual wafer map creation process, while the second pre-processing device 15-2 may perform the channel expansion process CP and the resizing process RP.

The first pre-processing device 15-1 may perform different processing techniques on the first raw wafer map RWM1 classified by the classification process. For example, the first pre-processing device 15-1 may perform the channel expansion process CP, the resizing process RP, the labeling process LP, and the virtual wafer map creation process on the first raw wafer map WRM1 included in the training dataset, and at least any one of the labeling process LP and the virtual wafer map creation process may be omitted for the first raw wafer map RWM1 included in the verification dataset and the test dataset. The first pre-processing device 15-1 may perform the labeling process LP on the first raw wafer map RWM1 included in the training dataset and transmit the pre-processed first wafer map WM1 to the neural network device 13, so that the labeled first wafer map WM1 may be used for supervised learning for the deep learning model MD.

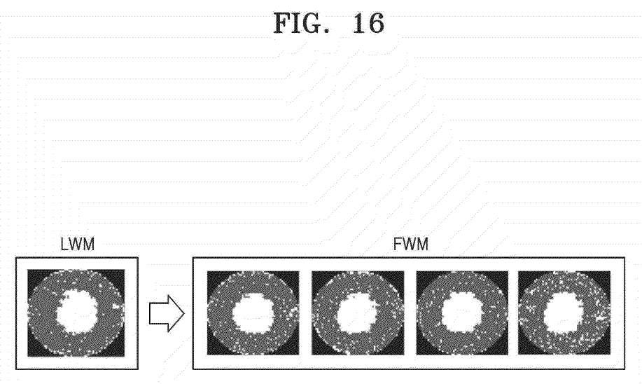

Hereinafter, the virtual wafer map creation process is described with reference to FIG. 16.

FIG. 16 is a view illustrating processing according to some example embodiments. In some example embodiments, FIG. 16 is a view illustrating the virtual wafer map creation process. Hereinafter, descriptions thereof are made with reference to FIGS. 2 to 15.

Referring to FIG. 16, a virtual wafer map FWM may be created to obtain training data for training the deep learning model MD. The virtual wafer map FWM may be created using a labeled wafer map LWM and a virtual wafer map created through a virtual wafer map creation process.

The virtual wafer map creation process may create the virtual wafer map FWM having a certain defect pattern, when learning data for the certain defect pattern is insufficient. For example, when ‘center’ type learning data, among the defect patterns of FIG. 15, is insufficient, a wafer map having the ‘center’ type pattern may be logically created.

For example, the virtual wafer map creation process may create the ‘center’ type virtual wafer map FWM by converting patterns such as straight lines and curves constituting the wafer map LWM labeled as ‘center’ based on a certain (and/or otherwise determined) logic. Alternatively, the virtual wafer map creation process may create the ‘center’ type virtual wafer map FWM by performing rotation, position movement, noise addition, noise deletion, and/or image integrating on the wafer map LWM labeled ‘center’. In this case, the virtual wafer map FWM may be created using Gaussian noise. The virtual wafer map FWM may be labeled by the labeling process described above with reference to FIG. 11.

The virtual wafer map creation process may be performed in the first pre-processing device 15-1 of FIG. 1. The first pre-processing device 15-1 may selectively perform the virtual wafer map creation process. By creating the virtual wafer map FWM, data necessary for creating the deep learning model MD performed in operation S10 of FIG. 2 may be supplemented. Accordingly, the learning ability of the deep learning model MD may be improved, and a defect pattern of the wafer map may be accurately analyzed.

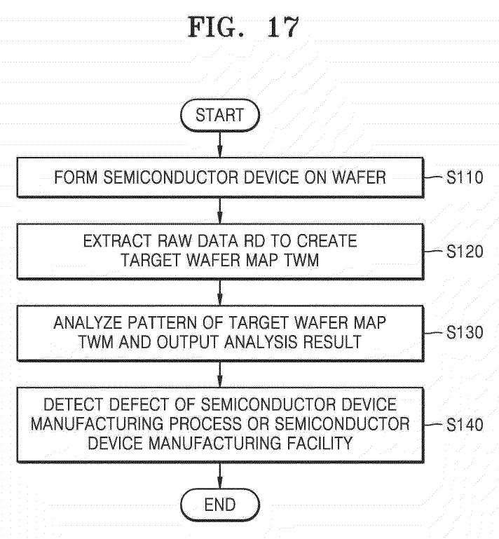

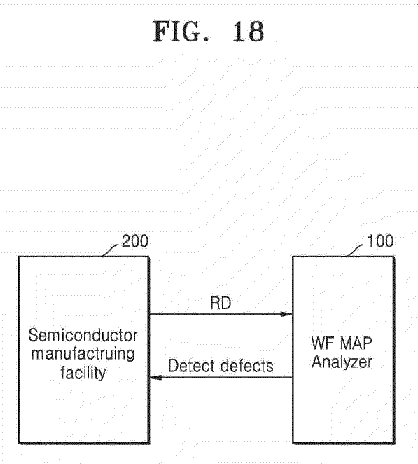

FIG. 17 is a flowchart illustrating a method of manufacturing a semiconductor device according to some example embodiments, and FIG. 18 is a block diagram illustrating a method of manufacturing a semiconductor device according to some example embodiments. In some example embodiments, FIG. 17 is a view illustrating a method of manufacturing a semiconductor device using the wafer map analysis method described above with reference to FIGS. 2 to 16. Hereinafter, descriptions thereof are made with reference to FIGS. 1 to 16.

Referring to FIGS. 17 and 18, in operation S110, a semiconductor manufacturing facility 200 may form a device and/or structure such as a semiconductor device (e.g., a transistor, capacitor, etc.) on a surface of a wafer through, e.g., a semiconductor device manufacturing processes. The semiconductor device manufacturing processes may include a deposition process, an etching process, a plasma process, an implant process, a drying process, and/or the like. The wafer may be diced and separated into a plurality of units later. For example, the wafer may be diced and separated into a plurality of chip units.

In operation S120, the semiconductor manufacturing facility 200 may acquire raw data RD by testing the wafer. The wafer on which the test is performed may be a FAB-out wafer on which a semiconductor device is formed, and/or a FAB-in wafer on which a semiconductor device is being formed. The raw data of FIG. 17 may correspond to the second raw data RD2 described above. The semiconductor manufacturing facility 200 may transmit the raw data RD obtained through the wafer to a wafer (WF) map analyzer 100.

The WF map analyzer 100 may correspond to, e.g., the analysis device 14 of FIG. 1. For example, the WF map analyzer 100 may include an apparatus to which the deep learning model MD output from the neural network device 13 of FIG. 1 is applied. The WF map analyzer 100 may include the second pre-processing device 15-2 of FIG. 1. Accordingly, the WF map analyzer 100 may receive the raw data RD. The raw data RD may correspond to the second raw data RD2 described above.

The WF map analyzer 100 may create a target wafer map TWM based on the raw data RD received from the semiconductor manufacturing facility 200. The target wafer map TWM may be created in the second pre-processing device 15-2. The target wafer map TWM may correspond to the second wafer map WM2 described above. The target wafer map TWM may be an image in which good and bad characteristics of each unit are displayed and mapped in a plan view of the wafer by performing the channel expansion process CP and the resizing process RP in the second pre-processing device 15-2.

In operation S130, the WF map analyzer 100 may analyze a pattern of the target wafer map TWM using the deep learning model MD learned using the neural networks (NN or NN') described above with reference to FIGS. 7 to 13. The WF map analyzer 100 may determine a defect type and/or source of the target wafer map TWM by analyzing the pattern of the target wafer map TWM.

The WF map analyzer 100 may output the determined defect type of the target wafer map TWM. For example, the WF map analyzer 100 may store and/or output the determined defect type in the raw data RD. However, the example embodiments are not limited thereto, and the WF map analyzer 100 may output a pattern analysis result of the target wafer map TWM in various manners. For example, the WF map analyzer 100 may store an analysis result of the target wafer map TWM in a storage medium such as the memory 12 and/or the additional storage as described above.

In operation S140, defects in the manufacturing process and/or manufacturing facility may be detected based on the output pattern analysis result of the target wafer map TWM. The pattern of the target wafer map TWM may indicate in which manufacturing process a problem occurred, in which manufacturing facility a defect occurred, and/or the like, depending on the defect type. Accordingly, by analyzing the pattern of the target wafer map TWM, defects in the manufacturing process or manufacturing facility may be easily tracked and precisely supplemented. In some example embodiments, the results of the operation S140 may be used to adjust and/or modify the manufacturing processes. For example, a path of the wafer through the facilities may be adjusted, a cleaning processes of a facility may be initiated, a duration and/or intensity of a manufacturing process, and/or the like may be adjusted to prevent and/or reduce the detected defects in the manufacturing processes. In some example embodiments, the results of operation S140 may be used to determine a method for correcting the detected defects, and/or to tag chip units which should be discarded and/or reprocessed.

In some example embodiments, the raw data RD may be obtained by performing a test on the wafer in the semiconductor manufacturing facility 200, but the example embodiments are not limited thereto. For example, the semiconductor manufacturing facility 200 may provide a wafer, and the WF map analyzer 100 may perform a test on the wafer to extract raw data RD. For example, both the wafer test and the analysis may be performed by the WF map analyzer 100.

Hereinafter, the WF map analyzer 100 is described in detail.

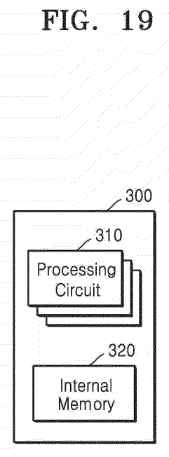

FIG. 19 is a block diagram illustrating a neural network device 300 according to some example embodiments. In some example embodiment, FIG. 19 is a view illustrating the neural network device 13 of FIG. 1. Hereinafter, descriptions thereof are made with reference to FIG. 1.

Referring to FIG. 19, the neural network device 300 may be a processor for a neural network. As noted above, the neural network device 300 may be, and/or include, the WF map analyzer 100. The neural network device 300 may perform computations on layers of the neural network. The neural network device 300 may receive the first wafer map WM1 from the first pre-processing device 15-1. The neural network device 300 may create the deep learning model MD using the neural networks NN and NN' described above with reference to FIGS. 7 to 13. The neural network device 300 may additionally update a defect type of the wafer map. As the defect type of the wafer map is updated, the neural network device 300 may learn the neural network model MD and evaluate performance thereof.

The neural network device 300 may include processing circuits 310 and an internal memory 320. The processing circuits 310 may perform an assigned computation. At least some of the processing circuits 310 may operate in parallel. At least some of the processing circuits 310 may operate independently. The processing circuits 310 may be implemented as hardware circuits. At least some of the processing circuits 310 may be a core circuit capable of executing instructions.

The internal memory 320 may store data (e.g., feature maps) created according to the computation performed by the processing circuits 310 and/or various types of data created during a computation process. The processing circuits 310 may share the internal memory 320. In some example embodiments, the processing circuits 310 may include, for example, the neural network device 13, the analysis device 14, and/or the pre-processing device 15, and/or the internal memory 320 may be, and/or be included in, the memory 12, as described in reference to FIG. 1. In some example embodiments, for example, the processing circuits 310 may include and/or be included in, but are not limited to, processing circuity such as hardware including logic circuits; a hardware/software combination such as a processor executing software; or a combination thereof. For example, the processing circuitry, more specifically, may include, but is not limited to, a central processing unit (CPU), an arithmetic logic unit (ALU), a digital signal processor, a microcomputer, a field programmable gate array (FPGA), and programmable logic unit, a microprocessor, application-specific integrated circuit (ASIC), etc.

Similarly, unless otherwise indicated, any of the functional blocks shown in the figures and described above may include and/or be implemented in the processing circuitry.

While the inventive concepts have been particularly shown and described with reference to some example embodiments thereof, it will be understood that various changes in form and details may be made therein without departing from the spirit and scope of the following claims.

1. A method of analyzing a wafer map using a neural network, the method comprising:
creating a wafer map based on raw data;
receiving, by an inception module including a plurality of inception layers, a first output feature map created based on the wafer map;
outputting, by the inception module, a final inception output feature map based on the first output feature map;
connecting the first output feature map to the final inception output feature map through a shortcut connection; and
performing an addition operation on the first output feature map and the final inception output feature map to output a second output feature map.

2. The method of claim 1, wherein
the inception module includes a first inception layer and a second inception layer that are sequentially arranged, and
the outputting of the final inception output feature map includes
receiving, by the first inception layer, the first output feature map and subsequently creating a first inception output feature map based on the first output feature map, and
receiving, by the second inception layer, the first inception output feature map and subsequently creating the final inception output feature map based on the first inception output feature map.

3. The method of claim 1, wherein
the plurality of inception layers each include a plurality of convolution layers, and
the outputting of the final inception output feature map includes
performing, in each of the plurality of inception layers, computations using the plurality of convolution layers, and
performing, by at least some of the plurality of convolution layers, computation in parallel.

4. The method of claim 3, wherein some of the plurality of convolution layers includes a 1X1 size filter.

5. The method of claim 3, wherein
the outputting of the final inception output feature map further includes
combining, in each of the plurality of inception layers, at least two of a plurality of output feature maps created as a result of the computation into a single feature map, and
normalizing, in each of the plurality of inception layers, the combined single feature map.

6. The method of claim 1, further comprising:
transmitting the first output feature map to an additional convolution layer, the additional convolution layer connected to the shortcut connection; and
creating, in the additional convolution layer, an additional output feature map based on the first output feature map, wherein the outputting of the second output feature map includes performing an addition operation on the additional output feature map and the final inception output feature map.

7. The method of claim 1, further comprising:
creating the first output feature map by extracting a feature of the wafer map and performing sub-sampling using at least one convolution layer and at least one pooling layer.

8. The method of claim 1, further comprising:
determining which defect type a pattern of the wafer map corresponds based on the second output feature map.

9. A method of analyzing a wafer map, the method comprising:
creating a first raw wafer map based on first raw data;
creating a first wafer map by processing the first raw wafer map; and
creating a deep learning model which has learned a defect pattern of the first wafer map using a neural network, the creating of the deep learning model including
creating a first output feature map by extracting characteristic information of the first wafer map using a first module configured to receive the first wafer map and performing sub-sampling on the characteristic information,
creating a second output feature map based on the first output feature map using a second module configured to receive the first output feature map, and determining a defect type of the first wafer map based on the second output feature map using a third module configured to receive the second output feature map, and
wherein the second module includes an inception module configured to receive the first output feature map, the inception module including a plurality of inception layers and a shortcut connection configured to connect the first output feature map to a final inception output feature map output from the inception module.

10. The method of claim 9, wherein the inception module includes:
a first inception layer configured to create a first inception output feature map based on the first output feature map after receiving the first output feature map; and
a second inception layer configured to create the final inception output feature map based on the first inception output feature map after the first inception output feature map is received.

11. The method of claim 9, wherein each of the plurality of inception layers includes:
a plurality of convolution layers, at least some of which are configured to perform in parallel;
a connection layer configured to receive at least two output feature maps of a plurality of output feature maps output from the plurality of convolution layers and to combine the at least two output feature maps into a single feature map; and a batch normalization layer configured to receive a feature map output from the connection layer and subsequently normalize the received feature map.

12. The method of claim 9, wherein
the creating the second output feature map further includes
receiving, by an (n-1)^{th} additional module, among a plurality of additional modules sequentially arranged between the second module and the third module and having a structure that is the same as a structure of the second module, an output feature map of the second module or a previous additional module, among the plurality of additional modules, and outputting an (n-1)^{th} additional output feature map based on the received output feature map,
receiving, by an nth additional module among the plurality of additional modules, the (n-1)^{th} additional output feature map and outputting the second output feature map based on the (n-1)^{th} additional output feature map,
wherein the determining of the defect type includes determining a defect type of the first wafer map using the third module, and
wherein n is an integer of 2 or greater.

13. The method of claim 9, wherein the processing includes at least one of a channel expansion process to expand a channel of the first raw wafer map, a resizing process to change a size of the first raw wafer map, a labeling process to designate a label on the first raw wafer map, a virtual wafer map additional creation process to create a virtual wafer map additionally, and a classification process to classify the first raw wafer map into a plurality of datasets.

14. The method of claim 13, wherein
the first wafer map is classified into a training dataset used to train the deep learning model, a verification dataset used to verify performance of the deep learning model while the deep learning model is being trained, or a test dataset used to verify the performance of the deep learning model after the training of the deep learning model is finished, and
the labeling process is performed on the first wafer map included in the training dataset.

15. The method of claim 9, further comprising:
creating a second raw wafer map based on second raw data that is different from the first raw data;
creating a second wafer map by processing the second raw wafer map;
analyzing a pattern of the second wafer map using the deep learning model; and
detecting a defect of at least one of a manufacturing process and manufacturing facility of the second wafer map based on a result of analyzing the pattern of the second wafer map.

16. The method of claim 15, wherein
the first wafer map is used to train the deep learning model, and
the second wafer map is an object to be analyzed using the deep learning model.

17. The method of claim 15, wherein the creating the second wafer map includes at least one of a channel expansion process to expand a channel of the second raw wafer map and a resizing process to change a size of the second raw wafer map.

18-24. (canceled)
